(19) United States
(12) Patent Application Publication
(10) Pub. No.: US 2023/0137865 A1
(43) Pub. Date: May 4, 2023

(54) FILM FORMING METHOD AND FILM FORMING APPARATUS

(71) Applicant: Tokyo Electron Limited, Tokyo (JP)

(72) Inventors: Takayuki KARAKAWA, Nirasaki City (JP); Kotaro MIYATANI, Nirasaki City (JP); Hideo NAKAMURA, Nirasaki City (JP); Katsushige HARADA, Hwaseong-si (KR); Yuichiro MOROZUMI, Nirasaki City (JP)

(21) Appl. No.: 18/049,661

(22) Filed: Oct. 26, 2022

(30) Foreign Application Priority Data
Nov. 1, 2021 (JP) 2021-179003

(51) Int. Cl. H01L 27/108; C23C 16/56; C23C 16/455; C23C 16/40; C23C 16/34

(52) U.S. Cl. CPC H01L 27/1085; C23C 16/56; C23C 16/45529; C23C 16/45544; C23C 16/404; C23C 16/34

(57) ABSTRACT

A method of forming a crystalline structure film containing strontium, titanium, and oxygen on a substrate, includes: forming an amorphous structure film on a surface of a titanium nitride film formed on a surface of the substrate, the amorphous structure film containing strontium and oxygen and having a titanium content adjusted so that a content ratio of titanium to strontium based on the number of atoms becomes a value in a range of 0 or more and less than 1.0; and obtaining a crystalline structure film containing strontium, titanium and oxygen and containing titanium diffused from the titanium nitride film by heating the substrate, on which the amorphous structure film is formed, at a temperature of 500 degrees C. or higher.

### CROSS-REFERENCE TO RELATED APPLICATION

This application is based upon and claims the benefit of priority from Japanese Patent Application No. 2021-179003, filed on Nov. 1, 2021, the entire contents of which are incorporated herein by reference.

### TECHNICAL FIELD

The present disclosure relates to a film forming method and a film forming apparatus.

### BACKGROUND

Further improvement in capacitor performance is required in an insulating film that constitutes, for example, a DRAM (Dynamic Random Access Memory) as a semiconductor device. Therefore, there is an increasing need for an ultra-high-k film having a dielectric constant of, for example, about 80 to 100 as a material for the insulating film. A crystal of a composite oxide containing strontium (Sr) and titanium (Ti) (hereinafter also referred to as “STO”) is known as a candidate for the ultra-high-k film.

For example, there is known a technique in which a first Sr—Ti—O-based film having a thickness of 10 nm or less formed on a Ru film is crystallized by annealing, and then a second Sr—Ti—O-based film is formed and crystallized by annealing.

[Prior Art Document]

[Patent Document]

Patent Document 1: International Publication No. 2009/104621

### SUMMARY

According to the present disclosure, a method of forming a crystalline structure film containing strontium, titanium, and oxygen on a substrate, includes: forming an amorphous structure film on a surface of a titanium nitride film formed on a surface of the substrate, the amorphous structure film containing strontium and oxygen and having a titanium content adjusted so that a content ratio of titanium to strontium based on the number of atoms becomes a value in a range of 0 or more and less than 1.0; and obtaining a crystalline structure film containing strontium, titanium and oxygen and containing titanium diffused from the titanium nitride film by heating the substrate on which the amorphous structure film is formed, at a temperature of 500 degrees C. or higher.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A and 1B are schematic diagrams showing a method of forming a crystalline structure STO film according to a first embodiment.

FIG. 2 is a plan view of a film forming apparatus for forming the STO film.

FIG. 3 is a vertical cross-sectional side view of a film forming part.

FIG. 4 is a vertical cross-sectional side view of a heat treatment part.

FIG. 5 is a diagram showing an example of a film forming sequence.

FIGS. 6A-1, 6A-2 and 6B are schematic diagrams showing a method of forming a crystalline structure STO film according to a second embodiment.

FIGS. 7A to 7D are schematic diagrams showing a method of forming a crystalline structure STO film according to a third embodiment.

FIG. 8 is a first diffraction spectrum diagram showing XRD analysis results of STO films according to an Example and a Comparative Example.

FIG. 9 is a graph showing a layered structure of the STO film.

FIG. 10 is a second diffraction spectrum diagram showing XRD analysis results of STO films according to Examples and a Comparative Example.

FIGS. 11A, 11B and 11C are first electron micrographs of surfaces of STO films according to Examples and a Comparative Example.

FIGS. 12A and 12B are second electron micrographs of the surfaces of STO films according to an Example and a Comparative Example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

<First Embodiment>

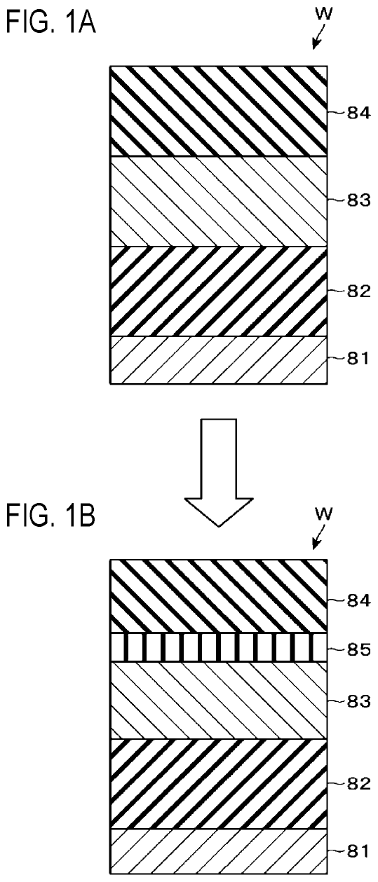

First, a method for forming a crystalline structure STO film according to the present disclosure (hereinafter also referred to as “crystalline STO film”) will be described with reference to FIGS. 1A and 1B. FIGS. 1A and 1B schematically show a layered structure of films formed on a semiconductor wafer (hereinafter referred to as “wafer”) W, which is a substrate, in a process of forming, for example, a DRAM. In FIGS. 1A and 1B, FIGS. 6A-1, 6A-2, and 6B, and FIGS. 7A to 7D, structures such as trenches and via holes formed in the wafer W are omitted.

As exemplified in FIG. 1A, in the wafer W on which the crystalline STO film is formed, a silicon oxide film (SiO film) 82 as a base film and a titanium nitride film (TiN film) 83 for making contact with a silicon wafer 81 through trenches and via holes (not shown) are layered on an upper surface of the main body of the silicon wafer 81. A crystalline STO film 85, which is an ultra-high-k film, is formed on the upper surface of the TiN film 83.

As a method of obtaining the crystalline STO film 85, there is known a technique in which an amorphous structure STO film (hereinafter also referred to as “amorphous STO film”) is formed on a wafer W to be subjected to film formation and the amorphous STO film is converted to a crystalline STO film by heat-treating (annealing) the wafer W.

Meanwhile, the inventors of the present disclosure have found that as shown in the experimental results in the later-described Examples, unlike ordinary metals, even if a heat treatment is performed after forming an amorphous STO film on the upper surface of the TiN film 83, a crystalline STO film may not be formed. In this case, it is also conceivable to adopt a technique in which another amorphous STO film is layered on the upper surface of the amorphous STO film and subjected to a heat treatment to obtain a crystalline STO film in a region not in contact with the TiN film 83 by performing the heat treatment of the another amorphous STO film. However, it was found that even if the crystalline STO film is obtained by this technique, irregularities called blisters may be formed on the surface of the crystalline STO film.

The reason that a crystalline STO film cannot be obtained even after a heat treatment is not clear. As for this point, the inventors speculated that if the content of titanium in the vicinity of the interface between the TiN film 83 and the amorphous STO film is high, there may be created conditions that make it difficult for STO crystals to grow.

Therefore, in the method of forming a crystalline STO film according to the first embodiment, as shown in FIG. 1A, a strontium oxide film (SrO film) 84 is formed on the surface of the TiN film 83 without adding titanium (amorphous STO film forming process). Thereafter, the wafer W, on which the SrO film 84 is formed, is subjected to a heat treatment to diffuse titanium from the TiN film 83 into the SrO film 84, thereby obtaining a crystalline STO film 85 (crystalline STO film obtaining process, FIG. 1B).

For example, when obtaining the crystalline STO film 85 having a thickness in the range of 1 nm to 5 nm, it is preferable to form the SrO film 84 having a thickness of 2 nm to 10 nm. Further, the heat treatment is carried out in an atmosphere of an inert gas such as an argon (Ar) gas or a nitrogen (N₂) gas, at a temperature of 500 to 700 degrees C., for example, 630 degrees C., for 5 minutes to 1 hour, for example, 1 hour.

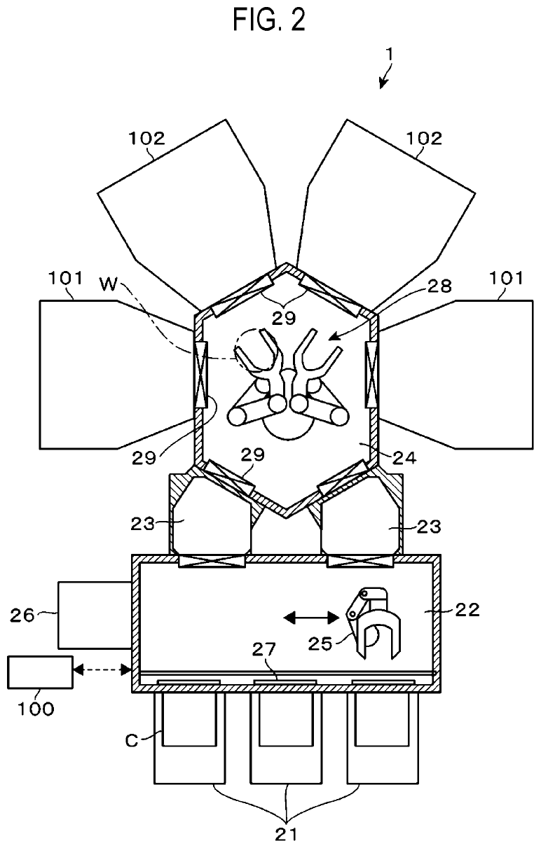

Hereinafter, the configuration of an apparatus (film forming apparatus 1) for forming the crystalline STO film 85 by performing the above-described process will be described with reference to FIGS. 2 to 4. The film forming apparatus 1 is configured, for example, as a multi-chamber system vacuum processing apparatus. As shown in FIG. 2, the film forming apparatus 1 includes an atmospheric pressure transfer chamber 22 which is kept at an atmospheric pressure by, for example, an Ar gas. A load port 21 for transferring the wafer W to and from, for example, a carrier C accommodating wafers W is installed in front of the atmospheric pressure transfer chamber 22. The front wall of the atmospheric pressure transfer chamber 22 is provided with an opening/closing door 27 that is opened when the wafer W is transferred to and from the carrier C. A transfer arm 25 for transferring the wafer W is provided in the atmospheric pressure transfer chamber 22. Further, an alignment chamber 26 for adjusting the orientation and eccentricity of the wafer W is provided on the left sidewall of the atmospheric pressure transfer chamber 22 when viewed from the load port 21 side.

A load lock chamber 23 is connected to the wall surface of the atmospheric pressure transfer chamber 22 opposite to the load port 21. The load lock chamber 23 has a function of switching the internal atmosphere between an atmospheric pressure atmosphere and a vacuum atmosphere while the wafer W is accommodated therein. For example, two load lock chambers 23 are arranged side by side when viewed from the atmospheric pressure transfer chamber 22 side. A vacuum transfer chamber 24 is arranged behind the load lock chambers 23 when viewed from the atmospheric pressure transfer chamber 22. The atmospheric pressure transfer chamber 22 and the vacuum transfer chamber 24 are connected to each load lock chamber 23 via a gate valve 29.

A film forming module (film forming part) 101 for forming the SrO film 84 on the upper surface of the TiN film 83 formed on the wafer W, and a heat treatment module (heat treatment part) 102 for forming a crystalline STO film 85 at the interface between the TiN film 83 and the SrO film 84 by heat-treating the wafer W on which the SrO film 84 is formed are connected to the vacuum transfer chamber 24. In this example, two film forming modules 101 and two heat treatment modules 102 are connected to the vacuum transfer chamber 24. A transfer arm 28 is provided in the vacuum transfer chamber 24. The wafer W is delivered among the load lock chamber 23, the film forming module 101, and the heat treatment module 102 by the transfer arm 28.

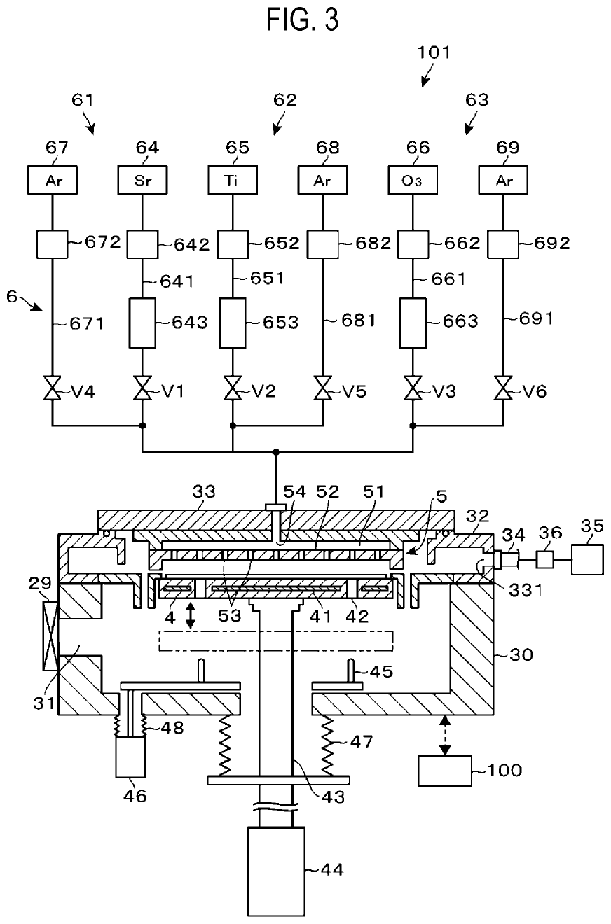

Next, a configuration example of the film forming module 101 for forming the SrO film 84 on the upper surface side of the TiN film 83 by an ALD (Atomic Layer Deposition) method will be described (FIG. 3). For the sake of convenience in description, the film forming module 101 shown in FIG. 3 is configured to be capable of forming a Sr-rich STO film 86 and an STO upper layer film 87 described in second and third embodiments. The formation of the SrO film 84 is different from the formation of the Sr-rich STO film 86 and the STO upper layer film 87 in that the provision of a Ti raw material gas supply part 62 for supplying a titanium (Ti) raw material gas is omitted or the Ti raw material gas supply part 62 is not used. In the following description, the configuration of the film forming module 101 including the Ti raw material gas supply part 62 will be described.

The film forming module 101 includes a processing container 30 that accommodates the wafer W. A loading/unloading port 31 that can be opened and closed by the gate valve 29 described above is formed on a side surface of the processing container 30.

For example, an annular exhaust duct 32 is arranged on an upper portion of the sidewall of the processing container 30. Furthermore, a top plate 33 is provided on an upper surface of the exhaust duct 32 so as to block the upper opening of the processing container 30. The processing container 30 is connected to an evacuation part 35 such as a vacuum pump or the like through an evacuation path 34 connected to an exhaust port 331 of the exhaust duct 32. An APC (auto pressure controller) valve 36 for adjusting an internal pressure of the processing container 30 is installed in the evacuation path 34.

A stage 4 which horizontally supports the wafer W is provided inside the processing container 30. A heater 41 for heating the wafer W is embedded in the stage 4. Further, the stage 4 is connected to an elevating mechanism 44 via a column 43 and is configured to be vertically movable by the elevating mechanism 44. In FIG. 3, the stage 4 moved to a wafer delivery position is indicated by a one-dot chain line. In FIG. 3, reference numeral 45 denotes support pins for use in delivering the wafer W, and the support pins 45 are configured to be vertically movable by a lifting mechanism 46. Reference numeral 42 denotes through-holes for the support pins 45, and reference numerals 47 and 48 denote bellows that expand and contract as the stage 4 and the support pins 45 are moved up and down.

A shower head 5 for supplying a processing gas into the processing container 30 is provided in the film forming module 101 so as to face the stage 4. The shower head 5 has a gas diffusion space 51 therein. The lower surface of the shower head 5 is configured as a shower plate 52 having a large number of gas discharge holes 53. A gas supply system 6 is connected to the gas diffusion space 51 through a gas introduction hole 54.

The gas supply system 6 includes a Sr raw material gas supply part 61 for supplying a strontium (Sr) raw material gas toward the processing container 30, a Ti raw material gas supply part 62 for supplying a Ti raw material gas toward the processing container 30, and an oxidizing gas supply part 63 for supplying an oxidizing gas for oxidizing the Sr raw material and the Ti raw material toward the processing container 30.

The Sr raw material supplied from the Sr raw material gas supply part 61 includes a strontium-containing compound such as Sr(Me5Cp)₂ (bispentamethylcyclopentadienyl strontium), Sr(THD)₂ (strontium bistetramethylheptanedionate), or the like. Further, the Ti raw material supplied from the Ti raw material gas supply part 62 includes a titanium-containing compound such as Ti(Me5Cp)(MeO)₃ (pentamethylcyclopentadienyl titanium trimethoxide), Ti(Me5Cp)(NMe₂)₃ (methylcyclopentadienyl titanium trimethoxide), or the like. Moreover, in this example, a highly reactive ozone (O₃) gas is used as the oxidizing gas. Alternatively, for example, remote plasma obtained by ionizing an oxygen gas may be supplied as the oxidizing gas.

The Sr raw material gas supply part 61 includes a gas source 64 for supplying the strontium (Sr) raw material gas and a strontium gas supply path 641. The Sr raw material gas source 64 has a function of bringing the above-described Sr raw material into contact with a carrier gas to vaporize or sublime the Sr raw material, and supplying the same as a raw material gas. For example, in the strontium gas supply path 641, a flow rate adjustment part 642, a storage tank 643, and a valve V1 are installed sequentially from the upstream side.

The Ti raw material gas supply part 62 includes a gas source 65 for supplying the Ti raw material gas and a titanium gas supply path 651. The Ti raw material gas source 65 has a function of bringing the aforementioned Ti raw material into contact with a carrier gas to vaporize or sublime the Ti raw material, and supplying the same as a raw material gas. For example, in the titanium gas supply path 651, a flow rate adjustment part 652, a storage tank 653, and a valve V2 are installed sequentially from the upstream side.

Further, the oxidizing gas supply part 63 includes an O₃ gas source 66 for supplying the oxidizing gas and an O₃ gas supply path 661. For example, in the O₃ gas supply path 661, a flow rate adjustment part 662, a storage tank 663, and a valve V3 are installed sequentially from the upstream side.

The Sr raw material gas, the Ti raw material gas, and O₃ are temporarily stored in storage tanks 643, 653, and 663, respectively, and are supplied to the film forming module 101 after being pressurized to a predetermined pressure. The supply and cutoff of the respective gases from the storage tanks 643, 653, and 663 to the film forming module 101 are performed by opening and closing the valves V1, V2, and V3.

Further, the gas supply system 6 includes an inert gas supply part for supplying an inert gas to the film forming module 101. For example, an Ar gas is used as the inert gas. The inert gas supply part in this example includes Ar gas sources 67, 68, and 69, and Ar gas supply paths 671, 681, and 691.

In this example, the Ar gas supplied from the Ar gas source 67 of the Sr raw material gas supply part 61 is a purge gas for the Sr raw material gas. The Ar gas source 67 is connected to the strontium gas supply path 641 on the downstream side of the valve V1 through the Ar gas supply path 671. Further, the Ar gas supplied from the Ar gas source 68 of the Ti raw material gas supply part 62 is a purge gas for the Ti raw material gas. The Ar gas source 68 is connected to the titanium gas supply path 651 on the downstream side of the valve V2 via the Ar gas supply path 681.

Furthermore, the Ar gas supplied from the Ar gas source 69 of the oxidizing gas supply part 63 is a purge gas for the oxidizing gas. The Ar gas source 69 is connected to the O₃ gas supply path 661 on the downstream side of the valve V3 via the Ar gas supply path 691. In FIG. 3, reference numerals 672, 682, and 692 indicate flow rate adjustment parts, respectively, and reference numerals V4, V5, and V6 indicate valves, respectively.

When forming the SrO film 84 (or the Sr-rich STO film 86 described later) on the upper surface of the TiN film 83 by the film forming module 101 shown in FIG. 3, the Sr raw material gas supply part 61 corresponds to a first raw material gas supply part, and the Ti raw material gas supply part 62 corresponds to a second raw material gas supply part.

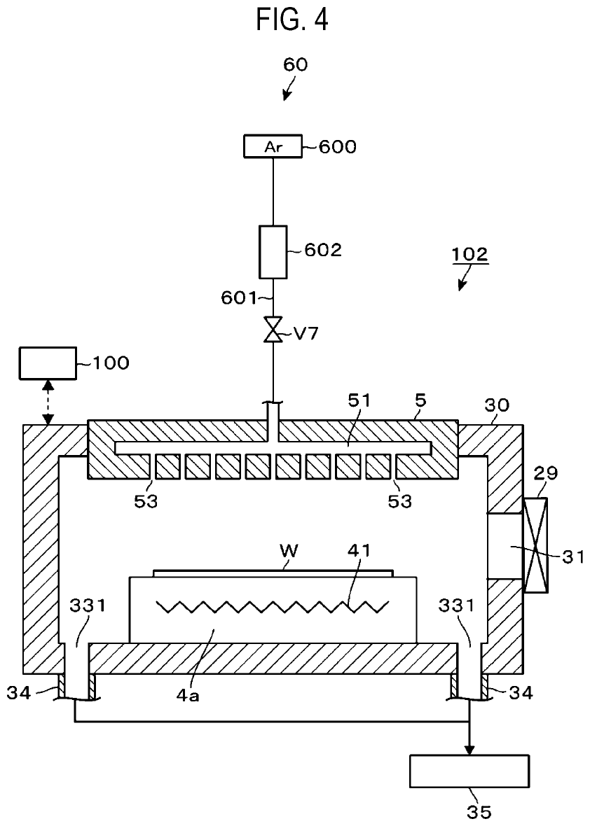

Next, the configuration of the heat treatment module 102 will be described with reference to FIG. 4. In FIG. 4, the components having the same functions as those of the film forming module 101 described with reference to FIG. 3 may be designated by the same reference numerals as those used in FIG. 3, and a duplicate description thereof may be omitted.

As shown in FIG. 4, the heat treatment module 102 includes a processing container 30, a stage 4a on which a wafer W to be processed is placed, and a shower head 5 installed on a ceiling surface side of the processing container 30 so as to face the stage 4a.

The stage 4a of this example is fixedly arranged on a bottom plate of the processing container 30. The wafer W on which the SrO film 84 has been formed in the film forming module 101 is placed on the stage 4a. A plurality of support pins (not shown) is provided inside the stage 4a so as to be movable up and down. The wafer W is delivered by allowing the support pins to protrude or retract with respect to the upper surface of the stage 4a.

A heater 41 for heating the wafer W to, for example, 630 degrees C. within the temperature range of 500 to 700 degrees C. is provided inside the stage 4a. A plurality of exhaust ports 331 for evacuating the interior of the processing container 30 is formed in the bottom plate around the stage 4a.

An inert gas supply part 60 for supplying an Ar gas, which is an example of an inert gas, to the processing container 30 is connected to the showerhead 5. The inert gas supply part 60 includes an Ar gas source 600 and an Ar gas supply path 601. For example, in the Ar gas supply path 601, a flow rate adjustment part 602 and a valve V7 are installed sequentially from the upstream side.

The film forming apparatus 1 having the above configuration includes a controller 100 as shown in FIG. 2. The controller 100 is configured with a computer including a storage part for storing a program, a memory, and a CPU. The program includes instructions (steps) which are combined so as to output control signals from the controller 100 to the respective parts of the film forming apparatus 1 to form the SrO film 84 on the wafer W and to perform the subsequent heat treatment. The program is stored in the storage part of the computer, such as a flexible disk, a compact disk, a hard disk, an MO disk (magneto-optical disk), a non-volatile memory, or the like. The program is read out from the storage part and installed in the controller 100.

The operation of the film forming apparatus 1 having the configuration described above will be described. First, a carrier C accommodating a plurality of wafers W is transferred to the load port 21 of the film forming apparatus 1. The SiO film 82 shown in the schematic diagram of FIG. 1A is formed on the upper surface of each wafer W. The wafer W is taken out from the carrier C by the transfer arm 25, loaded into the alignment chamber 26 through the atmospheric pressure transfer chamber 22, subjected to alignment, and then loaded into the vacuum transfer chamber 24 through the load lock chamber 23.

Subsequently, the wafer W is transferred to the film forming module 101 by the transfer arm 28, and the SrO film 84 is formed by an ALD method. The wafer W loaded into the processing container 30 is placed on the stage 4, and heating of the wafer W is started by raising the temperature of the heater 41 to a temperature within the range of 250 to 400 degrees C. Along with this heating operation, an Ar gas is supplied from the Ar gas sources 67, 68, and 69 into the processing container 30 at preset flow rates. Then, the interior of the processing container 30 is evacuated by the evacuation part 35, and the opening degree of the valve 36 is adjusted so that the internal pressure of the processing container 30 becomes a target pressure.

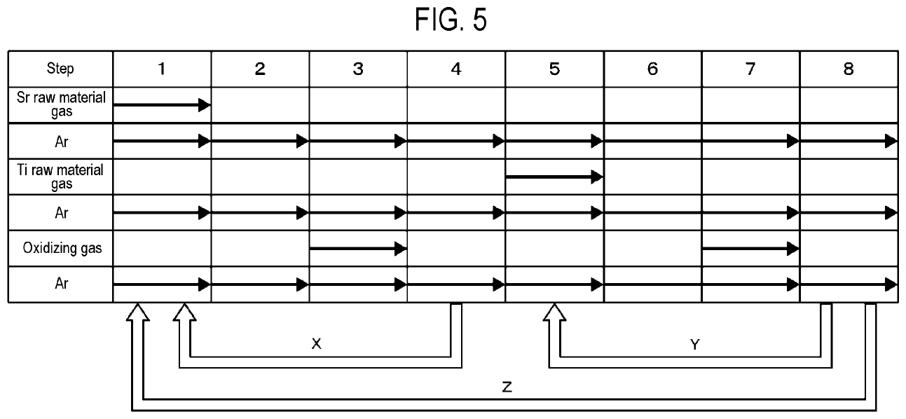

Subsequently, a process of forming a SrO film 84 is performed based on the film forming sequence of FIG. 5. In the case of forming the SrO film 84, only a cycle of operations 1 to 4 (first cycle) shown in FIG. 5 is executed. On the other hand, the number of execution times of the cycle of operations 5 to 8 (second cycle) is zero. First, the valve V1 is opened to supply the Sr raw material gas, and the Ar gas is supplied from the Ar gas sources 67, 68, and 69 at preset flow rates (operation 1). By this process, the Sr raw material is adsorbed on the entire surface of the wafer W.

Next, the valve V1 is closed to stop the supply of the Sr raw material gas, while the supply of the Ar gas from the Ar gas sources 67, 68, and 69 is continued. In this manner, purging with the Ar gas is performed to remove the Sr raw material gas remaining in the processing container 30 (operation 2).

Next, while continuing to supply the Ar gas from the Ar gas sources 67, 68, and 69, the valve V3 is opened to supply O₃, which is an oxidizing gas. By this process, the Sr raw material adsorbed to the wafer W reacts with O₃ to form a thin film of SrO (operation 3). When the Sr raw material is composed of an organometallic compound as in the example of the Sr raw material described above, the thin SrO film may contain a component containing carbon (e.g., SrCO₃, etc.). Subsequently, the valve V3 is closed to stop the supply of O₃, while the supply of the Ar gas from the Ar gas sources 67, 68, and 69 is continued. Purging with the Ar gas is performed to remove O₃ remaining in the processing container 30 (operation 4).

Thus, in the process of forming the SrO film 84, operations 1 to 4 of alternately supplying the Sr raw material gas and the oxidizing gas while supplying the Ar gas, which is an inert gas, into the processing container 30 is repeated by a predetermined number of cycles to form an SrO film 84 having a desired thickness. An example of the thickness of the SrO film 84 may be 10 nm, which is in the range of 2 nm or more and 10 nm or less.

After the formation of the SrO film 84 is completed, the wafer W is unloaded from the film forming module 101 and loaded into the heat treatment module 102 to perform a process of obtaining a crystalline STO film 85. That is, after the wafer W is placed on the stage 4a of the film forming module 101, the gate valve 29 is closed, and while the interior of the processing chamber 30 is being evacuated, the Ar gas is supplied from the inert gas supply part 60 to regulate the internal pressure of the processing container 30 to a preset pressure. In addition, electric power is supplied to the heater 41 from a power supply part (not shown) to heat the wafer W on the stage 4a to, for example, 630 degrees C. in the range of 500 to 700 degrees C.

By forming the SrO film 84 on the upper surface side of the TiN film 83, titanium diffuses from the TiN film 83 side to the SrO film 84 side due to a difference in concentration of titanium. The diffusion of titanium is promoted by heating the wafer W. Meanwhile, even when titanium moves toward the SrO film 84 by diffusion, the concentration of titanium may be lower than that of an amorphous STO film in the related art and may not be high enough to prevent the crystallization of the region containing strontium, titanium, and oxygen.

Therefore, by heat-treating the wafer W in which the SrO film 84 is formed on the TiN film 83, crystallization can be caused to occur in the region of the interface between the TiN film 83 and the SrO film 84 where titanium diffuses toward the SrO film 84. As a result, a crystalline STO film 85 can be obtained as shown in FIG. 1B.

For example, in order to obtain the crystalline STO film 85 having a thickness of 1 nm or more and 5 nm or less at the above-described heating temperature, the heat treatment is performed for a processing time of 5 minutes to 1 hour. The SrO film 84 remaining on the upper surface side of the crystalline STO film 85 may be removed by etching or CMP (Chemical Mechanical Polishing) after the wafer W is taken out from the film forming apparatus 1.

After heat-treating the wafer W for a preset period of time in the heat treatment module 102, the wafer W is taken out from the heat treatment module 102 and is transferred through the vacuum transfer chamber 24, the load lock chamber 23, and the atmospheric pressure transfer chamber in the opposite route to that used during the loading. The processed wafer W is accommodated in the original carrier C.

According to the film forming apparatus 1 of the present disclosure, the wafer W is heat-treated after the SrO film 84 containing no titanium is formed on the upper surface of the TiN film 83. As a result, an excessive increase in the titanium content at the interface between the TiN film 83 and the SrO film 84 can be suppressed, and the crystalline STO film 85 can be formed on the upper surface of the TiN film 83, which has conventionally been difficult to crystallize the amorphous STO film.

Here, the film formed on the upper surface of the TiN film 83 to obtain the crystalline STO film 85 by the method described with reference to FIGS. 1A and 1B is not limited to the SrO film 84 containing no titanium. For example, a strontium (Sr)-rich STO film having a relatively low content ratio of titanium to strontium (based on the number of atoms) may be used. The configuration of the Sr-rich STO film will be exemplified in the second embodiment described below.

<Second Embodiment>

FIGS. 6A-1, 6A-2 and 6B schematically show a method of forming the crystalline STO film 85 according to a second embodiment. In the second embodiment, a SrO film 84a (or a Sr-rich STO film 86) is formed to have a thickness in the range of 5 nm to 10 nm, which is close to the thickness of the crystalline STO film 85 formed on the upper surface side of the TiN film 83. The second embodiment is different from the first embodiment in which the interface region of the SrO film 84 is crystallized with the TiN film 83, in that the entire SrO film 84a (or Sr-rich STO film 86) is converted into the crystalline STO film 85 by heat treatment.

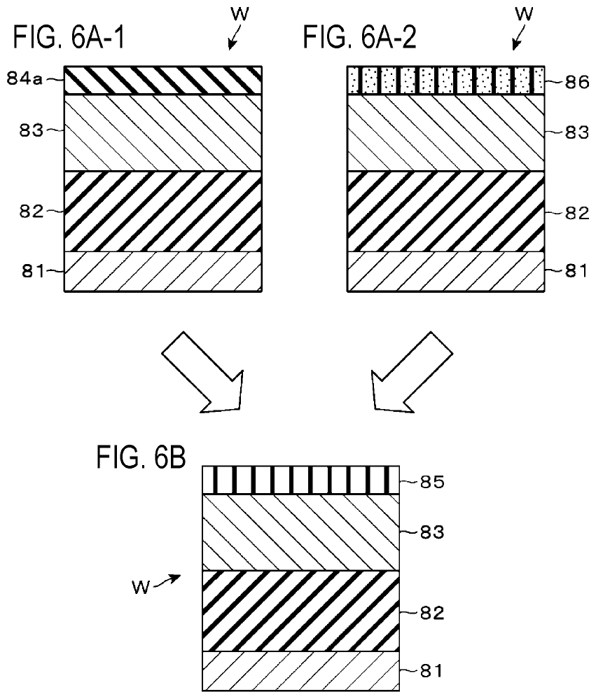

The film forming method of the SrO film 84a shown in FIG. 6A-1 is the same as that of the first embodiment except that as compared with the SrO film 84 shown in FIG. 1A (having a thickness of, for example, 2 nm or more and 10 nm or less), the SrO film 84a shown in FIGS. 6A-1, and 6A-2 has a thickness in the range of 5 nm to 10 nm. Further, the heat treatment method may also be the same as that of the first embodiment as long as the time for executing the heat treatment capable of converting the entire SrO film 84a into the crystalline STO film 85 can be ensured.

If the thickness of the titanium diffused from the TiN film 83 falls within a range that spreads over the entire SrO film 84a in the thickness direction, the entire SrO film 84a may be converted into the crystalline STO film 85 by the same mechanism as the example described in the first embodiment.

Further, the film that can be converted into the crystalline STO film 85 by heat treatment is not limited to the SrO film 84 containing no titanium. FIG. 6A-2 shows an example in which the Sr-rich STO film 86 having a relatively low content ratio of titanium to strontium is formed on the upper surface side of the TiN film 83. The Sr-rich STO film 86 is formed so that the content ratio of titanium to strontium on the basis of the number of atoms is in the range of more than 0 and less than 1.0, preferably more than 0 and less than or equal to 0.7. The thickness range of the Sr-rich STO film 86 is the same as that of the already-described SrO film 84a.

The Sr-rich STO film 86 can be formed by performing all operations 1 to 8 of the film forming sequence shown in FIG. 5 using the film forming module 101 (provided with the Ti raw material gas supply part 62) described with reference to FIG. 3.

That is, in forming the Sr-rich STO film 86, the cycle of operations 1 to 4 described above is performed to form a thin SrO film. Then, a cycle including supplying a Ti raw material gas, adsorbing the Ti raw material onto the wafer W (operation 5), stopping the supply of the Ti raw material gas, purging the interior of the processing container 30 (operation 6), supplying an oxidation gas (O₃) (operation 7), stopping the supply of the Ti raw material gas, and purging the interior of the processing container 30 (operation 8) is executed to form a thin film of TiO. Then, the cycle of operations 1 to 4 (first cycle) and the cycle of operations 5 to 8 (second cycle) are alternately repeated for a plurality of cycles. This makes it possible to form the Sr-rich STO film 86 having a desired thickness. In FIG. 5, the number of alternate repetitions of the first cycle and the second cycle is denoted as “Z”.

Here, the content ratio of titanium to strontium in the Sr-rich STO film 86 is adjusted by changing the ratio of the number of execution times of the first cycle (denoted as “X” in FIG. 5) to the number of execution times of the second cycle (denoted as “Y” in FIG. 5).

Specifically, composition analysis (e.g., secondary ion mass spectrometry, or the like) of the amorphous STO film obtained by changing the cycle ratio “X:Y” is performed in preliminary experiments. Then, within the range where the content ratio of titanium to strontium (based on the number of atoms) is greater than 0 and less than 1.0, the numbers of execution times of the respective cycles X and Y corresponding to the desired content ratio are adopted as the film forming conditions of the actual Sr-rich STO film 86.

As for the Sr-rich STO film 86 formed by the above-described method, just like the case of the SrO film 84a shown in FIG. 6A-1, the entire Sr-rich STO film 86 may be converted into the crystalline STO film 85 by a heat treatment using the heat treatment module 102.

<Third Embodiment>

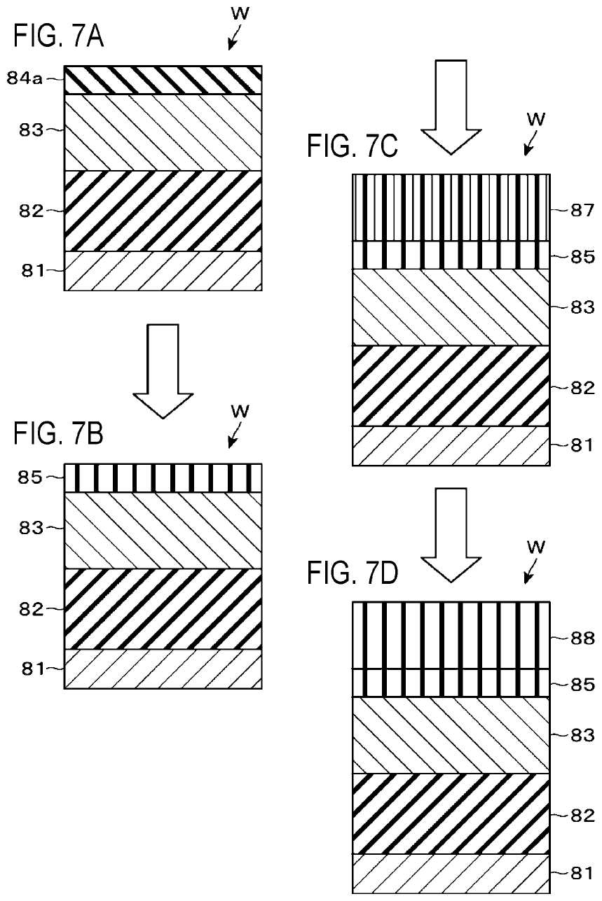

If the crystalline STO film 85 can be formed on the upper surface of the TiN film 83 by the method described in the first and second embodiments, it is possible to use the crystalline STO film 85 as a partition against the TiN film 83 and to form a thicker crystalline STO film. The third embodiment shown in FIGS. 7A to 7D is an example in which a crystalline STO film is formed by this method.

FIGS. 7A and 7B are re-illustration of FIGS. 6A-1 and 6B, respectively, showing an example in which a SrO film 84a is formed on the upper surface of a TiN film 83 and then subjected to a heat treatment to obtain a crystalline STO film 85. Subsequently, an STO upper layer film 87 having an amorphous structure is formed on the upper surface of the crystalline STO film 85 (see FIG. 7C).

The STO upper layer film 87 may be formed using the film forming module 101 including the Ti raw material gas supply part 62 described with reference to FIG. 3. The film forming module 101 for forming the STO upper layer film 87 corresponds to the upper layer film forming part of this example. As the upper layer film forming part, the same film forming module 101 as that for forming the SrO film 84 according to the first embodiment and the SrO film 84a and the Sr-rich STO film 86 according to the second embodiment may be used. Alternatively, a film forming module 101 other than the film forming module 101 for forming these films 84, 84a, and 86 may be connected to the vacuum transfer chamber 24.

The STO upper layer film 87 is formed to have a thickness of 3 nm or more and 30 nm or less, which is larger than the crystalline STO film 85. In addition, in the STO upper layer film 87, the content ratio of titanium to strontium based on the number of atoms may be set to a value of 1.0 or more. Since the STO upper layer film 87 does not make direct contact with the TiN film 83, the content ratio of titanium to strontium is not limited to the range of 0 or more and less than 1.0 and may be adjusted more freely. For example, when the conditions for obtaining a crystalline STO film having a higher relative dielectric constant is included in the range of the content ratio close to 1.0 or equal to or larger than 1.0, a high-quality STO upper layer film 87 may be formed without being subject to the restrictions for forming the crystalline STO film 85 on the upper surface of the TiN film 83. As a suitable content ratio in such a case, the STO upper layer film 87 may have the content ratio of titanium to strontium on the basis of the number of atoms falling within the range of 0.8 or more and 1.2 or less.

The STO upper layer film 87 formed by the above method may also be converted into a crystalline STO film 88 by a heat treatment using the heat treatment module 102. The upper layer film heat treatment part that heats the STO upper layer film 87 may be the same heat treatment module 102 as the one that heat-treats the SrO film 84 according to the first embodiment or the SrO film 84a and the Sr-rich STO film 86 according to the second embodiment. Alternatively, a heat treatment module 102 other than the heat treatment module 102 for forming the films 84, 84a, and 86 may be connected to the vacuum transfer chamber 24.

In the first to third embodiments described above, the film forming module 101 and the heat treatment module 102, which are single-substrate modules, are connected to the common vacuum transfer chamber 24. However, the present disclosure is not limited to the case where the process of forming the amorphous films (the SrO films 84 and 84a, and the Sr-rich STO film 86) and the process of converting the films 84, 84a, and 86 into the crystalline STO film 85 by the heat treatment are performed by the common film forming apparatus 1. For example, a batch-type processing apparatus, in which a boat holding a large number of wafers W is accommodated and processed in a heating furnace, may be used. The formation of amorphous films and the heat treatment thereof may be performed separately. As for the heat treatment, the wafer W may be heated by, for example, an RTA (Rapid Thermal Annealing) apparatus using an infrared lamp, for a treatment time shorter than the previously described 5 minutes. Further, when forming amorphous films, it may be possible to use a semi-batch type film forming apparatus in which a plurality of wafers W is arranged on a rotary table, revolved around a rotation axis, and allowed to pass through a plurality of processing spaces partitioned from each other to repeat adsorption of a raw material gas and formation of a thin film of SiO or TiO using an oxidizing gas.

Alternatively, for example, other modules such as a module for forming the TiN film 83, and the like may be connected to the vacuum transfer chamber 24 of the film forming apparatus 1 shown in FIG. 2. In this case, it is possible to form a layered structure of a plurality of types of films on the wafer W using the common film forming apparatus 1.

It should be considered that the embodiments disclosed herein are illustrative in all respects and not limitative. The embodiments described above may be omitted, substituted, or modified in various ways without departing from the scope and spirit of the appended claims.

(Experiment 1)

In correspondence to the first embodiment, a SrO film 84 was formed on the upper surface side of a TiN film 83 described with reference to FIGS. 1A and 1B. The difference in the film structure with and without a heat treatment was checked.

A. Experiment Conditions

(Example 1)

A TiN film 83 having a thickness of 10 nm was formed on a wafer W, and a SrO film 84 having a thickness of 10 nm was formed on the upper surface of the TiN film 83 by an ALD method based on operations 1 to 4 of FIG. 5. A cyclopentadienyl-based strontium compound was used as a Sr raw material, and the heating temperature of the wafer W was set to 350 degrees C. Thereafter, the wafer W was heated to 600 degrees C. under an argon gas supply atmosphere (at a pressure of 400 Pa (3 Torr)) and subjected to a heat treatment for 1 hour. The heat-treated wafer W was subjected to crystal structure analysis by XRD (X-Ray Diffraction) and cross section observation by TEM (Transmission Electron Microscope).

(Comparative Example 1)

The same analysis as in Example 1 was performed on a wafer W on which a SrO film 84 was formed and not subjected to a heat treatment.

B. Experimental Results

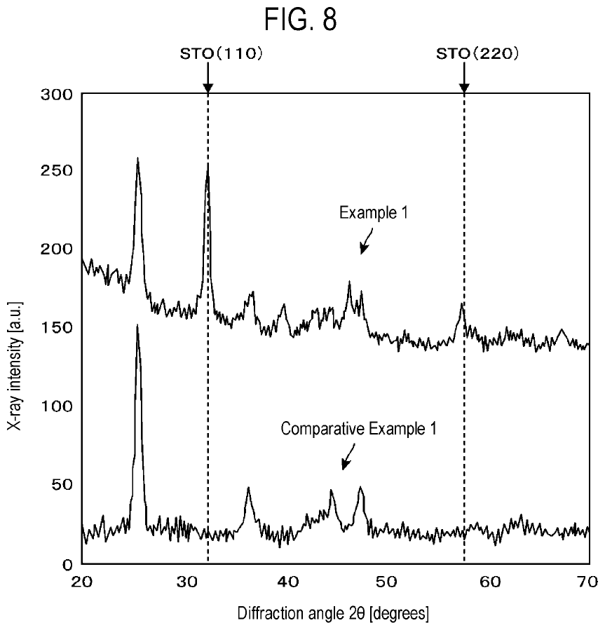

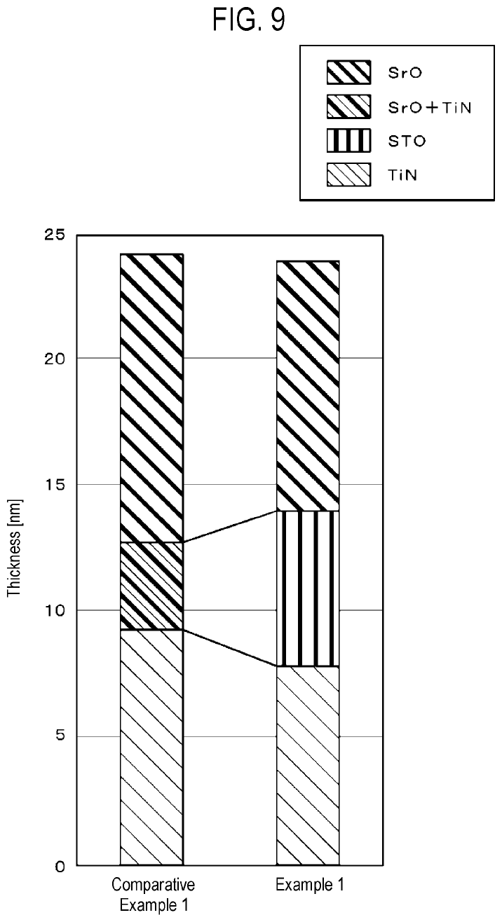

FIG. 8 shows the results of XRD analysis according to Example 1 and Comparative Example 1. The horizontal axis in FIG. 8 indicates the X-ray diffraction angle, and the vertical axis in FIG. 8 indicates the detected X-ray intensity. Further, FIG. 9 shows the results of summarizing the layered structure of the TiN film 83, the SrO film 84, and the crystalline STO film 85 based on the results of TEM observation as a stacked bar graph of the thickness of each layer.

According to the XRD analysis results shown in FIG. 8, in Example 1 in which the heat treatment is performed after the SrO film 84 is formed, an X-ray diffraction peak was confirmed at the diffraction angle corresponding to the crystal plane of the crystalline STO. This suggests that the crystalline STO film 85 is formed by heat-treating the wafer W after forming the SrO film 84 on the upper surface of the TiN film 83. On the other hand, in Comparative Example 1, no diffraction peak corresponding to crystalline STO was confirmed.

According to the TEM observation results shown in FIG. 9, it was confirmed that a layer having a thickness of about 6 nm is formed between the TiN film 83 and the SrO film 84 in Example 1. It can be understood that this layer corresponds to the crystalline STO film 85 which showed the diffraction peak corresponding to the crystal plane of the crystalline STO in the XRD analysis. Even in the TEM observation results of Comparative Example 1, a thin layer of about 3.5 nm was formed between the TiN film 83 and the SrO film 84. However, considering that the diffraction peak corresponding to the crystal plane of the crystalline STO could not be confirmed by the XRD analysis, it can be understood to be a mixed amorphous layer of SrO and SiN formed when the SrO film 84 was formed.

(Experiment 2)

In correspondence to the second embodiment, the film type of the film formed on the upper surface side of the TiN film 83 described with reference to FIGS. 6A-1, 6A-2 and 6B was changed to confirm the difference in the film structure after the heat treatment.

A. Experimental Conditions

(Example 2-1)

A SrO film 84a was formed under the same conditions as in Example 1, except that the thickness was set to 5 nm. Thereafter, the wafer W was heated to 630 degrees C. under an argon gas supply atmosphere (at a pressure of 400 Pa (3 Torr)) and subjected to a heat treatment for 1 hour. Crystal structure analysis by XRD and surface observation by SEM (Scanning Electron Microscope) were performed on the wafer W after the heat treatment.

(Embodiment 2-2)

Instead of the SrO film 84a, a Sr-rich STO film 86 having a content ratio of titanium to strontium of 9.4 (first cycle execution number X: first cycle execution number Y=10:1) was formed by an ALD method based on operations 1 to 8 of FIG. 5. This wafer W was analyzed in the same manner as in Example 2-1.

(Comparative Example 2-1)

An amorphous STO film having a content ratio of titanium to strontium of 1.0 (first cycle execution number X: first cycle execution number Y=2:3) was formed by the same method as in Example 2-1. This wafer W was subjected to the same heat treatment and analysis as in Example 2-1.

B. Experimental Results

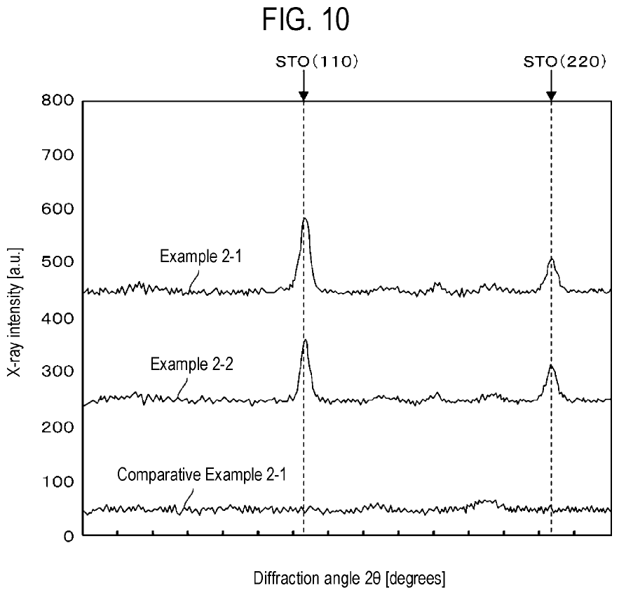

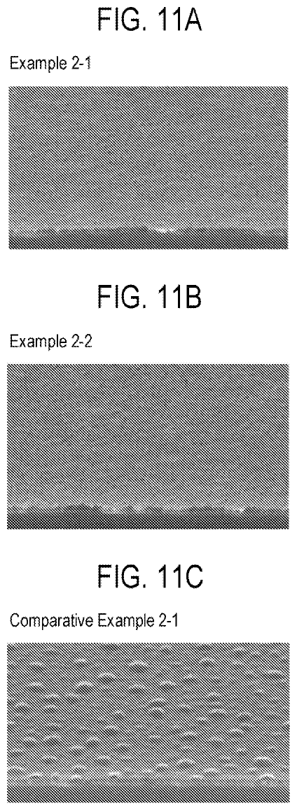

FIG. 10 shows the results of XRD analysis for Examples 2-1 and 2-2 and Comparative Example 2-1. The horizontal and vertical axes in FIG. 10 are the same as those in FIG. 8. SEM photographs of the surfaces of the respective wafers W are shown in FIGS. 11A to 11C.

According to the results of the XRD analysis shown in FIG. 10, in both Example 2-1 in which the SrO film 84a having a thickness of 5 nm was formed and Example 2-2 in which the Sr-rich STO film 86 having a thickness of 5 nm was formed, the diffraction peak corresponding to the crystalline STO was confirmed. From the results of this XRD analysis, it can be seen that the films 84a and 86 have been converted into crystalline STO films 85. On the other hand, in Comparative Example 2-1 having a high content ratio of titanium to strontium, no diffraction peak corresponding to the crystalline STO was confirmed.

Further, according to the SEM photographs shown in FIGS. 11A and 11B, the crystalline STO films 85 according to Examples 2-1 and 2-2 obtained by heat-treating the SrO film 84a and the Sr-rich STO film 86 have flat surfaces. On the other hand, according to FIG. 11C, a large number of protrusions called blisters were formed on the surface of the wafer W according to Comparative Example 2-2 obtained by heat-treating amorphous STO having a content ratio of titanium to strontium of 1.0. Such blisters are generated by partial peeling of the amorphous STO film, and are not desirable because they become a factor causing film peeling and deterioration of film characteristics such as a decrease in a dielectric constant.

(Experiment 3)

In correspondence to the third embodiment, the film type of the film formed on the lower surface side of the STO upper layer film 87 described with reference to FIGS. 7A to 7D was changed to confirm the difference in the film structure after the heat treatment.

A. Experimental Conditions

(Example 3-1)

An STO upper layer film 87 having a thickness of 20 nm and a content ratio of titanium to strontium of 1.0 was formed on the upper surface of the crystalline STO film 85 formed by the method described in Example 2-2. The method of forming the STO upper layer film 87 is the same as in Comparative Example 2-1. After forming the STO upper layer film 87, the wafer W was heated to 630 degrees C. under an argon gas supply atmosphere (at pressure of 400 Pa (3 Torr)) and subjected to a heat treatment for 1 hour. The surface of the wafer W after the heat treatment was observed by SEM.

(Comparative Example 3-1)

The STO upper layer film 87 was formed and heat-treated under the same conditions as in Example 3-1 except that an amorphous STO film having a content ratio of titanium to strontium of 1.0, which is formed by the method described in Comparative Example 2-1, is heat-treated and then the STO upper layer film 87 was formed on the upper surface of the amorphous STO film. The surface was observed by SEM.

B. Experimental Results

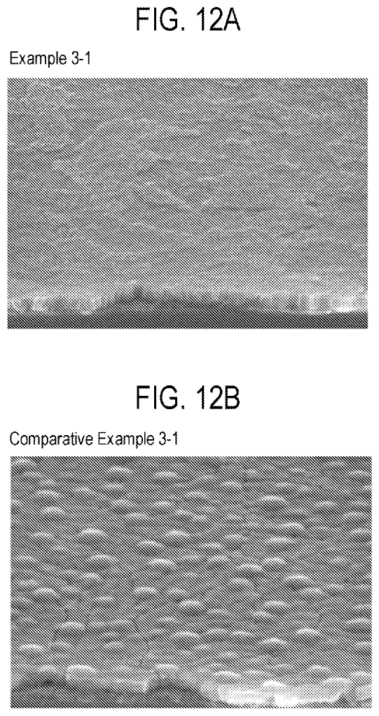

SEM photographs for Example 3-1 and Comparative Example 3-1 are shown in FIGS. 12A and 12B, respectively. In all experimental results, it was confirmed by XRD analysis that a crystalline STO film 88 was formed after the heat treatment of the STO upper layer film 87. According to the results shown in FIG. 12A, it can be confirmed that when the STO upper layer film 87 is formed on the upper surface of the flat crystalline STO film 85 shown in FIG. 11B, the surface of the crystalline STO film 88 after the heat treatment is also flat. On the other hand, according to the results shown in FIG. 12B, it can be noted that when the STO upper layer film 87 is formed on the surface of the film having blisters shown in FIG. 11C, blisters are also formed on the surface of the crystalline STO film 88 after the heat treatment.

According to the present disclosure in some embodiments, it is possible to form a crystalline structure film containing strontium, titanium, and oxygen on a titanium nitride film.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a crystalline structure film containing strontium, titanium, and oxygen on a substrate, the method comprising:
forming an amorphous structure film on a surface of a titanium nitride film formed on a surface of the substrate, the amorphous structure film containing strontium and oxygen and having a titanium content adjusted such that a content ratio of titanium to strontium based on the number of atoms becomes a value in a range of 0 or more and less than 1.0; and
obtaining a crystalline structure film containing strontium, titanium and oxygen and containing titanium diffused from the titanium nitride film by heating the substrate, on which the amorphous structure film is formed, at a temperature of 500 degrees C. or higher.

2. The method of claim 1, wherein in the forming the amorphous structure film, the amorphous structure film having a thickness of 2 nm or more is formed, and in the obtaining the crystalline structure film, the crystalline structure film is formed at an interface between the titanium nitride film and the amorphous structure film.

3. The method of claim 2, wherein the crystalline structure film has a thickness in a range of 1 nm or more and 5 nm or less.

4. The method of claim 1, wherein in the forming the amorphous structure film, the amorphous structure film having a thickness in a range of 5 nm or more and 10 nm or less is formed, and in the obtaining the crystalline structure film, the amorphous structure film is converted to the crystalline structure film.

5. The method of claim 4, further comprising:
forming an amorphous structure upper layer film containing strontium, titanium, and oxygen on an upper surface of the crystalline structure film after the obtaining the crystalline structure film; and
subsequently, converting the amorphous structure upper layer film into the crystalline structure film containing strontium, titanium, and oxygen by heating the substrate on which the amorphous structure upper layer film is formed at a temperature of 500 degrees C. or higher.

6. The method of claim 5, wherein the amorphous structure upper layer film is formed to have a thickness of 3 nm or more.

7. The method of claim 6, wherein the amorphous structure upper layer film has a content ratio of titanium to strontium based on the number of atoms in a range of 0.8 or more and 1.2 or less.

8. The method of claim 5, wherein the amorphous structure upper layer film has a content ratio of titanium to strontium based on the number of atoms in a range of 0.8 or more and 1.2 or less.

9. An apparatus for forming a crystalline structure film containing strontium, titanium, and oxygen on a substrate, comprising:
a film forming part configured to form an amorphous structure film on a surface of a titanium nitride film formed on a surface of the substrate, the amorphous structure film containing strontium and oxygen and having a titanium content adjusted such that a content ratio of titanium to strontium based on the number of atoms becomes a value in a range of 0 or more and less than 1.0; and
a heat treatment part configured to obtain a crystalline structure film containing strontium, titanium and oxygen and containing titanium diffused from the titanium nitride film by heating the substrate, on which the amorphous structure film is formed, at a temperature of 500 degrees C. or higher.

10. The apparatus of claim 9, wherein the film forming part includes:
a processing container configured to accommodate the substrate on which the titanium nitride film is formed;
a first raw material gas supply part configured to supply a strontium raw material gas containing strontium to the processing container;
a second raw material gas supply part configured to supply a titanium raw material gas containing titanium to the processing container; and
an oxidizing gas supply part configured to supply an oxidizing gas for oxidizing the strontium raw material and the titanium raw material to the processing container,
the apparatus further comprising:
a controller configured to output control signals for repeatedly executing: a first cycle that includes supplying the strontium raw material gas from the first raw material gas supply part to the substrate inside the processing container to cause the strontium raw material to be adsorbed onto the substrate, and subsequently, supplying the oxidizing gas from the oxidizing gas supply part to the substrate to oxidize the strontium raw material; and a second cycle that includes supplying the titanium raw material gas from the second raw material gas supply part to cause the titanium raw material to be adsorbed onto the substrate, and subsequently, supplying the oxidizing gas from the oxidizing gas supply part to the substrate to oxidize the titanium raw material,
wherein the content ratio in the amorphous structure film is adjusted by a ratio of the number of execution times of the first cycle to the number of execution times of the second cycle.

11. The apparatus of claim 10, wherein in the film forming part, the amorphous structure film having a thickness of 2 nm or more is formed, and wherein in the heat treatment part, the crystalline structure film is formed at an interface between the titanium nitride film and the amorphous structure film by the heat treatment.

12. The apparatus of claim 11, wherein the crystalline structure film has a thickness in a range of 1 nm or more and 5 nm or less.

13. The apparatus of claim 10, wherein in the heat treatment part, the amorphous structure film having a thickness in a range of 5 nm or more and 10 nm or less is formed, and wherein in the heat treatment part, the amorphous structure film is converted into the crystalline structure film by the heat treatment.

14. The apparatus of claim 13, further comprising:
an upper layer film forming part configured to form an amorphous structure upper layer film containing strontium, titanium, and oxygen on an upper surface of the crystalline structure film after the heat treatment in the heat treatment part; and
an upper layer film heat treatment part configured to perform a heat treatment to convert the amorphous structure upper layer film into the crystalline structure film containing strontium, titanium, and oxygen by heating the substrate, on which the amorphous structure upper layer film is formed, at a temperature of 500 degrees C. or higher.

15. The apparatus of claim 14, wherein in the upper layer film forming part, the amorphous structure upper layer film having a thickness of 3 nm or more is formed.

16. The apparatus of claim 15, wherein the amorphous structure upper layer film has a content ratio of titanium to strontium based on the number of atoms in a range of 0.8 or more and 1.2 or less.

17. The apparatus of claim 14, wherein the amorphous structure upper layer film has a content ratio of titanium to strontium based on the number of atoms in a range of 0.8 or more and 1.2 or less.

18. The apparatus of claim 9, wherein in the film forming part, the amorphous structure film having a thickness of 2 nm or more is formed, and
wherein in the heat treatment part, the crystalline structure film is formed at an interface between the titanium nitride film and the amorphous structure film by the heat treatment.

19. The apparatus of claim 9, wherein in the heat treatment part, the amorphous structure film having a thickness in a range of 5 nm or more and 10 nm or less is formed, and
wherein in the heat treatment part, the amorphous structure film is converted into the crystalline structure film by the heat treatment.
